(19) United States
(12) Patent Application Publication
(10) Pub. No.: US 2012/0180868 A1
(43) Pub. Date: Jul. 19, 2012

(54) III-NITRIDE FLIP-CHIP SOLAR CELLS

(75) Inventors: Robert M. Farrell, Goleta, CA (US); Carl J. Neufeld, Goleta, CA (US); Nikholas G. Toledo, Goleta, CA (US); Steven P. DenBaars, Goleta, CA (US); Umesh K. Mishra, Montecito, CA (US); James S. Speck, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/279,131

(22) Filed: Oct. 21, 2011

Related U.S. Application Data
(60) Provisional application No. 61/405,492, filed on Oct. 21, 2010.

(51) Int. Cl. H01L 31/0264; H01L 31/18

(52) U.S. Cl. 136/262; 438/94; 257/E31.02

(57) ABSTRACT

A III-nitride photovoltaic device structure and method for fabricating the III-nitride photovoltaic device that increases the light collection efficiency of the III-nitride photovoltaic device. The III-nitride photovoltaic device includes one or more III-nitride device layers, and the III-nitride photovoltaic device functions by collecting light that is incident on the back-side of the III-nitride device layers. The III-nitride device layers are grown on a substrate, wherein the III-nitride device layers are exposed when the substrate is removed and the exposed III-nitride device layers are then intentionally roughened to enhance their light collection efficiency. The collection of the incident light via the back-side of the device simplifies the fabrication of the multiple junctions in the device. The III-nitride photovoltaic device may include grid-like contacts, transparent or semi-transparent contacts, or reflective contacts.

### CROSS REFERENCE TO RELATED APPLICATION

This application claims the benefit under 35 U.S.C. Section 119(e) of the following co-pending and commonly-assigned application:

U.S. Provisional Patent Application Ser. No. 61/405,492, filed on Oct. 21, 2010, by Robert M. Farrell, Carl J. Neufeld, Nikholas G. Toledo, Steven P. DenBaars, Umesh K. Mishra, James S. Speck, and Shuji Nakamura, entitled “III-NITRIDE FLIP-CHIP SOLAR CELLS,” attorneys' docket number 30794.388-US-P1 (Jan. 24, 2011);

which application is incorporated by reference herein.

### STATEMENT REGARDING FEDERALLY SPONSORED RESEARCH AND DEVELOPMENT

This invention was made with U.S. Government support under Grant No. HR0011-10-1-0049 awarded by DARPA. The U.S. Government has certain rights in this invention.

### BACKGROUND OF THE INVENTION

1. Field of the Invention

This invention is related to semiconductor materials, methods, and devices, and more particularly, to the manufacturing and fabrication of III-nitride photovoltaic devices, such as solar cells.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

The usefulness of III-nitride material system has been well established for the fabrication of visible and ultraviolet light-emitting devices and high-frequency and high-power electronic devices. More recently, though, the III-nitride material system has begun to gain attention for use in photovoltaic (PV) applications. [1-5]

The III-nitride material system has several properties which give it key advantages over existing materials currently used in high-efficiency solar cells. To increase device efficiency beyond current levels, it will be necessary to move toward devices with increasing numbers of cells with bandgaps that span the entire solar spectrum. Unlike other III-V based alloys, which have bandgaps limited to less than ˜2.5 eV, the bandgap of InGaN-based alloys ranges from 0.7 eV for InN to 3.4 eV for GaN, which spans nearly the entire solar spectrum. [8] Moreover, InGaN alloys have a direct bandgap for the entire range of In compositions and therefore have very high absorption coefficients on the order of 1×10⁵ cm⁻¹. [9] These large absorption coefficients allow for the absorption of large amounts of light in very thin layers, enabling the growth of high-quality pseudo-morphic device structures and potentially leading to significant cost savings.

Unlike III-nitride-based light-emitting devices and high-frequency and high-power electronic devices, which are now commercially available, III-nitride solar cells are still in the research and development stage. Among the limited reports of III-nitride solar cells in the scientific literature, all of the devices have functioned by collecting light that was incident on the top-side of the III-nitride device layers. [1-5] In the case of III-nitride LEDs, significant improvements in light extraction efficiency were demonstrated for devices with back-side light-emitting geometries compared to devices with traditional top-side light-emitting geometries. [6,10] Likewise, in the case of III-nitride solar cells, similar improvements in light collection efficiency should be possible for devices with back-side light collection geometries compared to devices with top-side light collection geometries.

Nonetheless, there is a need in the art for improved techniques for providing III-nitride solar cells. The present invention satisfies this need.

### SUMMARY OF THE INVENTION

To overcome the limitations in the prior art described above, and to overcome other limitations that will become apparent upon reading and understanding the present specification, the present invention discloses a III-nitride photovoltaic device structure and method for fabricating the III-nitride photovoltaic device that increases the light collection efficiency of the III-nitride photovoltaic device. Specifically, the III-nitride photovoltaic device is comprised of one or more III-nitride device layers, and the III-nitride photovoltaic device functions by collecting light that is incident on the back-side of the III-nitride device layers.

The III-nitride device layers are grown on a substrate, wherein a planar or patterned wafer may be used as the substrate for growth of the III-nitride device layers. The substrate may be removed from the III-nitride device layers, wherein the III-nitride device layers are exposed when the substrate is removed and the exposed III-nitride device layers are then intentionally roughened to enhance their light collection efficiency.

The III-nitride device layers may contain one or more junctions of varying bandgaps, wherein a plurality of junctions with varying bandgaps improve overall device efficiency by spanning a broader spectrum associated with the incident light. The collection of the incident light via the back-side of the device simplifies the fabrication of the multiple junctions.

Variations in the structure of contacts is possible as well. The III-nitride photovoltaic device may include grid-like contacts, transparent or semi-transparent contacts, or reflective contacts.

### BRIEF DESCRIPTION OF THE DRAWINGS

Referring now to the drawings in which like reference numbers represent corresponding parts throughout:

FIG. 1 is a cross-sectional schematic illustrating the top-side and the back-side of the III-nitride device layers.

FIG. 2 is a cross-sectional schematic of a flip-chip solar cell grown on a planar sapphire substrate.

FIG. 3 is a cross-sectional schematic of a flip-chip solar cell grown on a patterned sapphire substrate.

FIG. 4 is a cross-sectional schematic of a roughened thin-film flip-chip solar cell with a grid-like p-contact.

FIG. 5 is a cross-sectional schematic of a tandem III-nitride flip-chip solar cell grown on a planar sapphire substrate.

FIG. 6 is a cross-sectional schematic of a roughened thin-film flip-chip solar cell with a transparent or semi-transparent p-contact.

FIG. 7 is a cross-sectional schematic of a roughened thin-film flip-chip solar cell with a reflective p-contact.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention comprises a structure and method to increase the light collection efficiency of III-nitride photovoltaic devices, such as solar cells.

The term “III-nitrides” refers to any alloy composition of the (Ga,Al,In,B)N semiconductors having the formula Ga_{w}AlₓIn_{y}B_{z}N where 0≦w≦1, 0≦x≦1, 0≦y≦1, 0≦z≦1, and w+x+y+z=1. Accordingly, it will be appreciated that the discussion of the invention hereinafter in reference to GaN and InGaN materials is applicable to the formation of various other (Ga,Al,In,B)N material species. Further, (Ga,Al,In,B)N materials within the scope of the invention may further include minor quantities of dopants and/or other impurity or inclusional materials.

Previously reported III-nitride solar cells functioned by collecting light that was incident on the top-side of the III-nitride device layers. [1-5] In the context of this invention, the term “back-side” refers to the side of the III-nitride device layers that are closest to the substrate on which they are grown or deposited, whereas the word “top-side” refers to the side of the III-nitride device layers that are furthest from the substrate on which they are grown or deposited. It is implied in this definition that the III-nitride device layers are grown during a process that is distinct from the substrate manufacturing process and that the III-nitride device layers are grown or deposited on only one side of the substrate, as is typically the case for semiconductor devices.

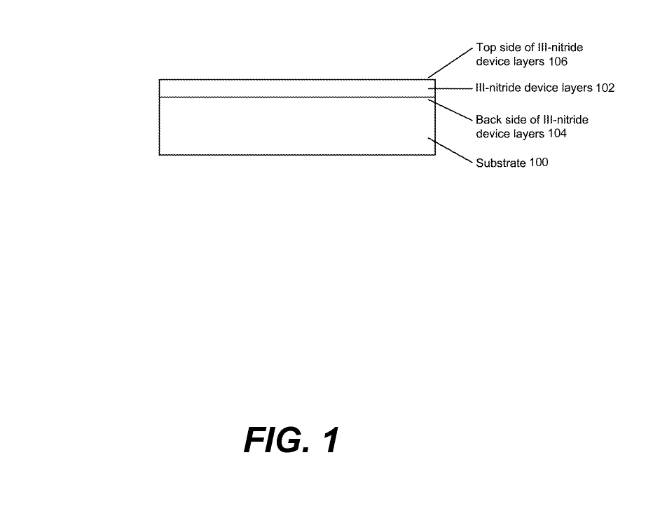

These definitions are illustrated in FIG. 1, which is a cross-sectional schematic illustrating the top-side and the back-side of the III-nitride device layers. FIG. 1 includes a substrate 100 and III-nitride device layer(s) 102, wherein the back-side 104 and top-side 106 of the III-nitride layers 102 are separately labeled and identified.

In contrast to previously reported III-nitride solar cells, this invention describes a structure and method for collecting light that is incident on the back-side of the III-nitride device layers of a III-nitride photovoltaic device. This type of device structure is referred to herein as a “flip-chip” device.

In the context of this invention, the term “flip-chip” refers to any device which functions by collecting light that is incident on the back-side of the III-nitride device layers and would typically involve mounting the top-side of the III-nitride device layers to a carrier wafer. In the context of this invention, the term “carrier wafer” refers to a wafer or other piece of mechanically stable material onto which the top-side of the III-nitride device layers is mounted or bonded. The purpose of the carrier wafer is to provide mechanical stability for the device, to remove heat from the device, and/or to enable further processing of the back-side of the device. This is analogous to the case of a flip-chip light-emitting diode (LED), [6] wherein the top-side of the III-nitride device layers is typically mounted to a carrier wafer and light is emitted from the back-side of the III-nitride device layers. Use of a flip-chip device geometry in conjunction with other variations in device design should improve device efficiency by increasing the path length for light absorption [7] in the active layers of the device and by reducing the light absorption in the other layers of the device.

### Technical Description

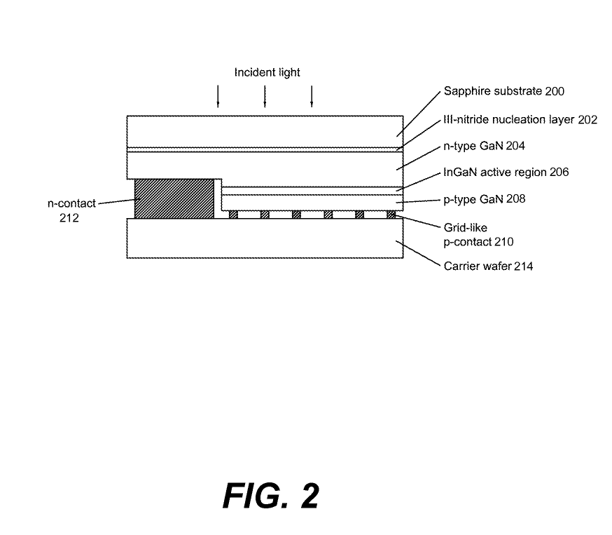

FIG. 2 is a cross-sectional schematic of a flip-chip III-nitride photovoltaic device, i.e., solar cell, grown on a planar sapphire substrate. FIG. 2 includes a sapphire substrate 200, III-nitride nucleation layer 202, n-type GaN layer(s) 204, InGaN active region 206, p-type GaN layer(s) 208, grid-like p-contact 210, n-contact 212, and carrier wafer 214, wherein incident light is shown striking the sapphire substrate 200.

In this context of this invention, the term “flip-chip solar cell” refers to a photovoltaic device which is grown on a planar substrate, has the substrate intact in the final device structure, and is designed for collecting light incident on the back-side of the III-nitride device layers and producing a flow of electrons in response thereto. The advantage of a flip-chip III-nitride solar cell over a conventional III-nitride solar cell is that, in the case of a flip-chip solar cell, the incident light encounters the active region prior to reaching the absorbing metal contacts. Although such a device could be fabricated in many different ways, one such method is described below.

First, the III-nitride device layers are grown on the top-side of a substrate by a growth technique such as metalorganic chemical vapor deposition (MOCVD) or molecular beam epitaxy (MBE). In the device shown in FIG. 2, the substrate 200 is made of c-plane sapphire and the III-nitride layers are grown on the Ga-face of the c-plane of the wurtzite crystal structure, as is the case for most commercially-available III-nitride light-emitting devices. The layers of the device typically include a III-nitride nucleation (or buffer) layer 202, a Si-doped n-type GaN layer 204, an undoped InGaN active region 206, and a Mg-doped p-type GaN layer 208. After growing the III-nitride device layers, metal contacts and mesas arefabricated by standard device processing techniques. In the device shown in FIG. 2, a grid-like metal p-contact 210 is deposited on the surface of the p-type GaN layers 208, so that the majority of low-energy photons are not absorbed by the III-nitride device layers and are transmitted through the structure to be absorbed by one or more smaller bandgap solar cells. Following the deposition of the p-contact 210, a mesa is dry etched through the active region 206 to electrically isolate the device and an n-contact 212 is deposited on the exposed n-type GaN layer 204. Finally, the device is flipped over (as shown in FIG. 2) and the top-side of the device is bonded to a carrier wafer 214. As discussed above, the purpose of this carrier wafer 214 is to provide mechanical stability for the device, to remove heat from the device, and/or to enable further processing of the back-side of the device.

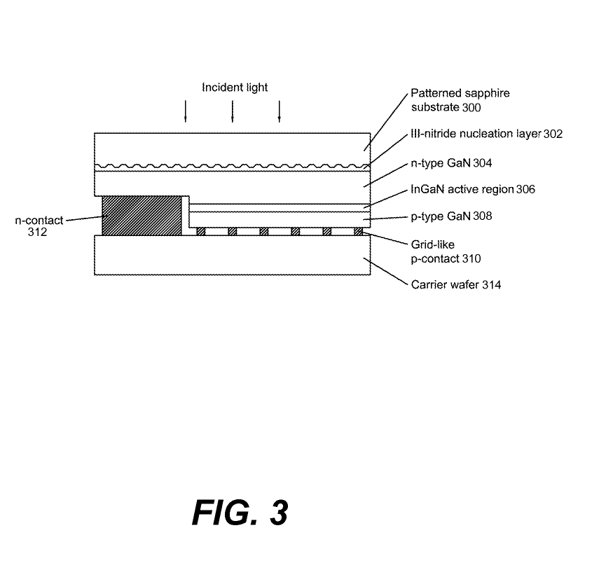

FIG. 3 is a cross-sectional schematic of a flip-chip III-nitride photovoltaic device, i.e., solar cell, grown on a patterned sapphire substrate, which is a variation on the device shown in FIG. 2. FIG. 3 includes a patterned sapphire substrate 300, III-nitride nucleation layer 302, n-type GaN layer(s) 304, InGaN active region 306, p-type GaN layer(s) 308, grid-like p-contact 310, n-contact 312, and carrier wafer 314, wherein incident light is shown striking the patterned sapphire substrate 300.

The structure of this device is nearly identical to the device described in FIG. 2, except that a patterned sapphire wafer is used as the substrate 300 for growing the III-nitride device layers, instead of a planar sapphire wafer, as shown in FIG. 2. The purpose of the patterned sapphire substrate 300 is to reduce the dislocation density in the III-nitride device layers and to scatter the incident light to improve the light collection efficiency. [11] Scattering the incident light increases the path length of the light as it passes through the active region 306, which increases the total amount of light absorbed in the active region 306 for a given active region 306 thickness. [7] This increase in path length decreases the total amount of material in the active region 306 needed for a given amount of absorption, which can potentially lead to significant cost savings and can reduce the likelihood of plastic relaxation in strained active regions.

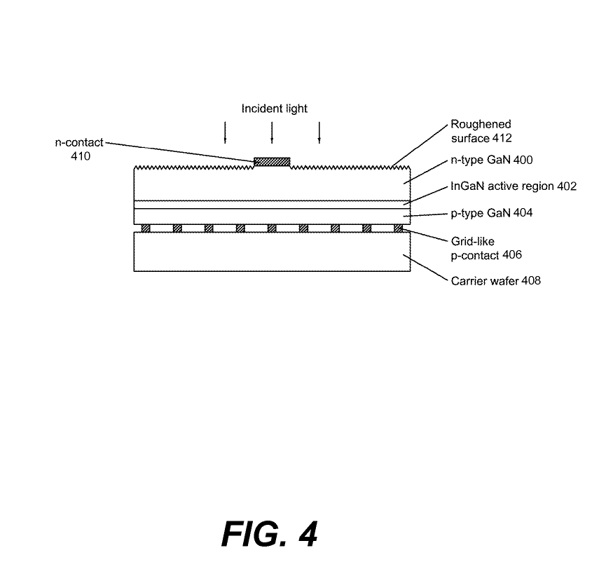

FIG. 4 is a cross-sectional schematic of a roughened thin-film flip-chip III-nitride photovoltaic device, i.e., solar cell, with a grid-like p-contact. FIG. 4 includes n-type GaN layer(s) 400, InGaN active region 402, p-type GaN layer(s) 404, grid-like p-contact 406, carrier wafer 408, and n-contact 410, wherein the original substrate has been removed and the exposed surface of the III-nitride device layers (i.e., the n-type GaN layers 400) has been roughened 412 to improve the light collection efficiency. Incident light is shown striking the roughened surface 412 of the n-type GaN layers 400 and the n-contact 410.

In the case of III-nitride LEDs, similar device geometries have been used to significantly improve the light extraction efficiency compared to devices with traditional top-side light-emitting geometries. [6,10] Although such a device could be fabricated in many different ways, one such method is described below.

First, the III-nitride device layers are grown on the top-side of a substrate by a growth technique, such as metalorganic chemical vapor deposition (MOCVD) or molecular beam epitaxy (MBE). In the device shown in FIG. 4, the original substrate (not shown) is made of c-plane sapphire and the III-nitride layers are grown on the Ga-face of the c-plane of the wurtzite crystal structure, as is the case for most commercially-available III-nitride light-emitting devices. The layers of the device typically include a III-nitride nucleation (or buffer) layer (not shown), a Si-doped n-type GaN layer 400, an undoped InGaN active region 402, and a Mg-doped p-type GaN layer 404. After growing the III-nitride device layers, a grid-like metal p-contact 406 is deposited on the surface of the p-type GaN layer 404, so that the majority of low-energy photons are not absorbed by the III-nitride device layers and are transmitted through the structure to be absorbed by one or more smaller bandgap solar cells. Following the deposition of the p-contact 406, the device is flipped over and the top-side of the device is bonded to a carrier wafer 408. After bonding the top-side of the device to the carrier wafer 408, the sapphire substrate is removed by a laser lift-off (LLO) process. [10] Next, the remaining Ga droplets from the LLO process are removed by wet etching and then the GaN is thinned to expose the n-type GaN layer 400. Then, an n-type contact 410 is formed on the exposed nitrogen-face n-type GaN 400 surface. Finally, PEC etching is used to roughen 412 the exposed nitrogen-face n-type GaN 400 surface by creating hexagonal pyramids bound by {10-1-1} facets. [12,13]

The devices shown in FIGS. 2, 3, and 4 all contain a single p-n junction for the purposes of illustration. However, similar devices could be created with multiple junctions with varying bandgaps to improve the overall device efficiency. This type of configuration, commonly referred to as a tandem solar cell, has already been demonstrated in other III-V materials. [14] For efficient operation, it is best to design tandem solar cells so that the band gaps of the various junctions span the solar spectrum and so that the incident light reaches the junction with the largest bandgap first, the junction with the second largest bandgap next, the junction with third largest bandgap next, and so on. For a III-nitride solar cell designed for collecting light incident on the top-side of the III-nitride device layers, fabricating such a structure would require growing the junction with the smallest bandgap first, growing the junction with the second smallest bandgap next, growing the junction with the third smallest bandgap next, and so on. Since smaller bandgaps are associated with higher indium mole fractions for the III-nitride material system, fabricating this structure would require growing the active regions with higher indium mole fractions before growing the active regions with lower indium mole fractions. Previous studies, however, have shown that the optimum growth temperature for high indium mole fraction alloys is generally lower than the optimum growth temperature for low indium mole fraction alloys and that layers containing high indium mole fraction alloys can be thermally damaged during the growth of subsequent high temperature layers. [15] Thus, it would be difficult to grow a tandem III-nitride solar cell that is designed for collecting light on the top-side of the III-nitride device layers without thermally damaging the active regions with high indium mole fractions.

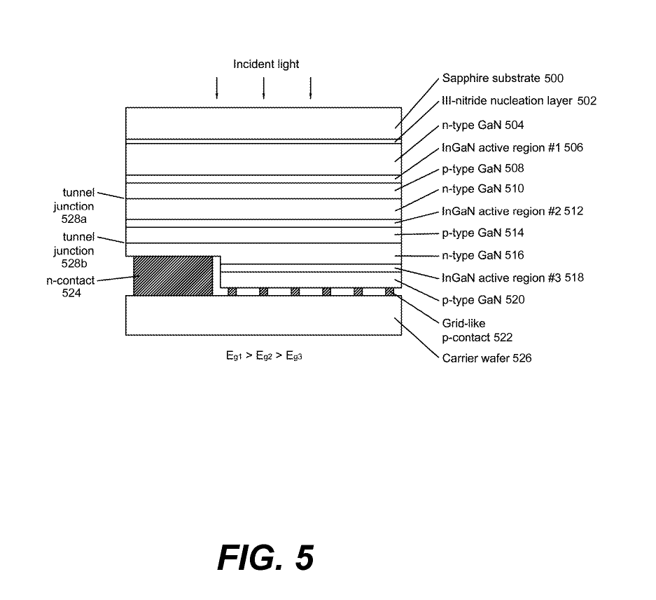

FIG. 5 is a cross-sectional schematic of a tandem flip-chip III-nitride photovoltaic device, i.e., solar cell, grown on a planar sapphire substrate. FIG. 5 includes a sapphire substrate 500, III-nitride nucleation layer 502, n-type GaN layer(s) 504, InGaN active region #1 506, p-type GaN layer(s) 508, n-type GaN layer(s) 510, InGaN active region #2 512, p-type GaN layer(s) 514, n-type GaN layer(s) 516, InGaN active region #3 518, p-type GaN layer(s) 520, grid-like p-contact 522, n-contact 524, and carrier wafer 526, wherein incident light is shown striking the sapphire substrate 500.

In this design, the junction (InGaN active region #1 506) with the largest bandgap (E_{g1}) is grown first, the junction (InGaN active region #2 512) with the second largest bandgap (E_{g2}) is grown next, the junction (InGaN active region #3 518) with the third largest bandgap (E_{g3}) is grown next, and so on. As is typically the case for GaAs-based tandem solar cells, each forward-biased junction is connected to the next forward-biased junction by a reverse-biased tunnel junction 528a, 528b. [14] For such a configuration, the active regions with high indium mole fractions would be less likely to be thermally damaged, because the active regions for each successive junction are grown at progressively lower temperatures. For the purposes of illustration, the tandem solar cell shown in FIG. 5 is depicted in a standard flip-chip solar cell geometry, similar to the device shown in FIG. 2. However, the advantages of using a tandem solar cell configuration in a flip-chip device geometry are general and could be applied to any the device configurations described above or below.

The devices shown in FIGS. 2, 3, 4, and 5 all contain a grid-like p-contact, so that the majority of low-energy photons that are not absorbed by the III-nitride device layers are transmitted through the structure to be absorbed by one or more smaller bandgap solar cells. However, these configurations are simply for the purpose of illustration, and similar devices could be created with alternative p-contact configurations.

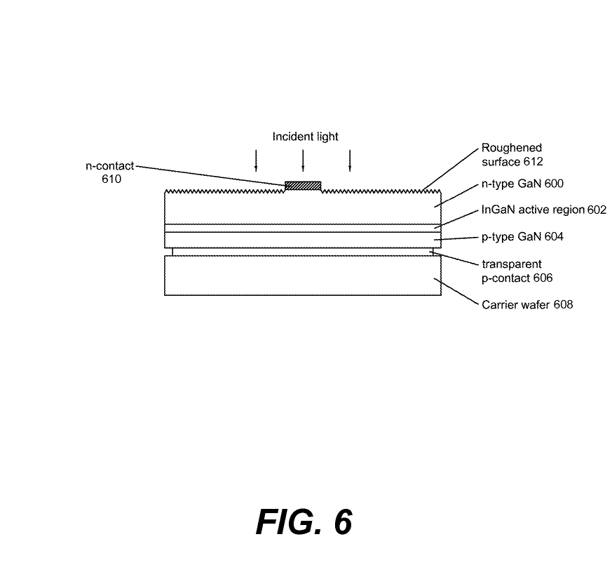

FIG. 6 is a cross-sectional schematic of a roughened thin-film flip-chip III-nitride photovoltaic device, i.e., solar cell, with a transparent or semi-transparent p-contact, which is similar to the device shown in FIG. 4, except that the grid-like p-contact has been replaced by a transparent or semi-transparent p-contact. FIG. 6 includes n-type GaN layer(s) 600, InGaN active region 602, p-type GaN layer(s) 604, transparent p-contact 606, carrier wafer 608, and n-contact 610, wherein the original substrate has been removed and the exposed surface of the III-nitride device layers (i.e., the n-type GaN layers 600) has been roughened 612 to improve the light collection efficiency. Incident light is shown striking the roughened surface 612 of the n-type GaN layers 600 and the n-contact 610.

This type of p-contact 606 would be used in a situation similar to the grid-like p-contact, where the majority of low-energy photons that are not absorbed by the III-nitride solar cell are transmitted through the structure to one or more smaller bandgap solar cells. This type of p-contact 606 could be made with transparent conducting oxide such as indium tin oxide [16] or with one or more semi-transparent thin metal layers. [17]

The devices shown in FIGS. 2, 3, 4, 5, and 6 all contain p-contacts that were designed to let the majority of low-energy photons that are not absorbed by the III-nitride device layers pass through the structure to be absorbed by one or more smaller bandgap solar cells. However, these configurations are simply for the purpose of illustration, and the p-contacts can be designed to reflect any light that was transmitted through the III-nitride device layers on the first pass through the device.

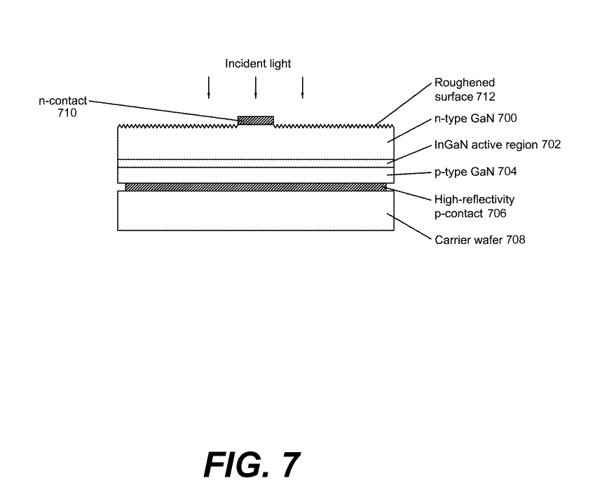

FIG. 7 is a cross-sectional schematic of a roughened thin-film flip-chip III-nitride photovoltaic device, i.e., solar cell, with a reflective p-contact, which is similar to the device shown in FIG. 4, except that the grid-like p-contact has been replaced by a reflective thick metal contact. FIG. 7 includes n-type GaN layer(s) 700, InGaN active region 702, p-type GaN layer(s) 704, high reflectivity p-contact 706, carrier wafer 708, and an n-contact 710, wherein the original substrate has been removed and the exposed surface of the III-nitride device layers (i.e., the n-type GaN layers 700) has been roughened 712 to improve the light collection efficiency. Incident light is shown striking the roughened surface 712 of the n-type GaN layers 700 and the n-contact 710.

The advantage of this configuration is that it doubles the effective path length of the light in the active region(s) 702 by creating a second pass for the light through the III-nitride device layers. Although this configuration increases the effective path length of the light in the active region(s) 702, it precludes integration with smaller bandgap solar cells and would probably work best in a monolithic tandem solar cell made entirely of III-nitrides, such as the device shown in FIG. 5.

Possible Modifications

The III-nitride solar cells described above were grown on c-plane sapphire substrates. However, the scope of this invention includes the growth of III-nitride solar cells on all possible crystallographic orientations of all possible foreign substrates. These foreign substrates include, but are not limited to, silicon carbide, silicon dioxide, silicon, zinc oxide, boron nitride, lithium aluminate, lithium niobate, germanium, aluminum nitride, lithium gallate, partially substituted spinels, and quaternary tetragonal oxides sharing the γ-LiAlO₂ structure.

The scope of this invention also covers III-nitride solar cells grown on crystallographic orientations other than the c-plane orientation cited in the technical description. This idea is also pertinent to all polar, nonpolar, and semipolar planes that can be used for growing III-nitride semiconductor devices. The term “nonpolar plane” includes the {11-20} planes, known collectively as a-planes, and the {10-10} planes, known collectively as m-planes. The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero l Miller index.

This invention also covers the selection of particular crystal polarities. The use of curly brackets, { }, throughout this document denotes a family of symmetry-equivalent planes. Thus, the {10-12} family includes the (10-12), (−1012), (1-102), (−1102), (01-12), and (0-112) planes. All of these planes are Ga-polarity, meaning that the crystal's c-axis points away from the substrate. Likewise, the {10-1-2} family includes the (10-1-2), (−101-2), (1-10-2), (−110-2), (01-1-2), and (0-11-2) planes. All of these planes are N-polarity, meaning that the crystal's c-axis will point towards the substrate. All planes within a single crystallographic family are equivalent for the purposes of this invention, though the choice of polarity can affect the behavior of the growth process. In some applications it would be desirable to grow on N-polarity planes, while in other cases growth on Ga-polarity planes would be preferred. Both polarities are acceptable for the practice of this invention.

Furthermore, variations in III-nitride nucleation (or buffer) layers and nucleation layer growth methods are acceptable for the practice of this invention. The growth temperature, growth pressure, orientation, and composition of the nucleation layers need not match the growth temperature, growth pressure, orientation, and composition of the subsequent thin films and heterostructures. The scope of this invention includes the growth of III-nitride solar cells on all possible substrates using all possible nucleation layers and nucleation layer growth methods.

The preferred embodiment presented above discussed the growth of c-plane III-nitride solar cells on foreign substrates. However, the scope of this invention includes the growth of polar, nonpolar, or semipolar III-nitride solar cells on all possible free-standing polar, nonpolar, or semipolar III-nitride wafers created by all possible crystal growth methods and wafer manufacturing techniques.

Variations in solar cell active region and heterostructure design are possible without departing from the scope of the present invention. The specific thickness and composition of the layers are variables inherent to particular device designs and may be used in alternative embodiments of the present invention. For instance, the c-plane solar cells in the preferred embodiment of the invention utilize InₓGa₁₋ₓN-based layers for the active region. However, the scope of this invention also includes solar cells which utilize layers of any alloy composition of Ga_{w}AlₓIn_{y}B_{z}N (where 0≦w≦1, 0≦x≦1, 0≦y≦1, 0≦z≦1, and w+x+y+z=1) for the active region. Likewise, the c-plane solar cells in the preferred embodiment of the invention utilize p-type GaN and n-type GaN layers for carrier transport between the active region and the contacts. However, the scope of this invention also includes solar cells which utilize layers of any alloy composition of Ga_{w}AlₓIn_{y}B_{z}N (where 0≦w≦1,0≦x≦1,0≦y≦1,0≦z≦1, and w+x+y+z=1) for carrier transport between the active region and the contacts.

The preferred embodiment of this invention discussed growing the III-nitride device layers by MOCVD or MBE. However, different growth methods could be used in alternative embodiments of the present invention. Other potential growth methods include HVPE, LPE, CBE, PECVD, sublimation, and sputtering.

The III-nitride solar cells described above were comprised of multiple homogenous layers. However, the scope of this invention also includes III-nitride solar cells comprised of multiple layers having varying or graded compositions.

Additional impurities or dopants can also be incorporated into the III-nitride thin films described in this invention. For example, Fe, Mg, Si, and Zn are frequently added to various layers in III-nitride heterostructures to alter the conduction properties of those and adjacent layers. The use of such dopants and others not listed here are within the scope of the invention.

Some of the III-nitride solar cells described above were grown on patterned sapphire substrates. However, the scope of this invention includes the growth of III-nitride solar cells on all possible crystallographic orientations of all possible patterned substrates. These substrates include, but are not limited to, silicon carbide, silicon dioxide, silicon, zinc oxide, boron nitride, lithium aluminate, lithium niobate, germanium, aluminum nitride, lithium gallate, partially substituted spinels, and quaternary tetragonal oxides sharing the γ-LiAlO₂ structure. Moreover, in the preferred embodiment, the substrate was patterned on the surface on which the III-nitride device layers were grown. However, the substrate may have also been patterned on the back surface or at an interface inside the substrate itself. The scope of this invention involves the growth of III-nitride solar cells on any patterned substrate, regardless of the physical location of the substrate patterning.

Some of the III-nitride solar cell structures described above involved removing the sapphire substrate by laser lift-off (LLO). However, the substrate may have been removed by any other possible substrate removal method, such as wet etching, dry etching, grinding, lapping, polishing, or other wafer thinning or removal technique. All possible substrate removal methods are within the scope of this invention.

Some of the III-nitride solar cells described above involved roughening an exposed nitrogen-face c-plane GaN surface by PEC etching. However, the exposed III-nitride device layers could have been roughened by any other surface roughening technique. All surface roughening techniques are within the scope of this invention. Moreover, in the preferred embodiment, the exposed surface that was roughened was a nitrogen-face c-plane GaN surface. However, the exposed surface could have been of any crystallographic orientation or of any polarity. The roughening of all possible exposed surfaces of all possible crystallographic orientations and polarities is within the scope of this invention.

Some of the III-nitride solar cells described above contained a transparent p-contact made of a transparent conducting film such as indium tin oxide. However, the scope of this invention also includes flip-chip solar cells containing transparent p-contacts made of any possible material. These possible materials include, but are not limited to, conductive polymers and transparent conductive oxides such as ZnO, In₂O₃, SnO₂, and CdO, as well as multicomponent oxides consisting of combinations of ZnO, In₂O₃, SnO₂, and CdO. Additional impurities or dopants could also be incorporated into the transparent conducting films. For example, Al, Ga, In, and Sn are frequently added to transparent conducting oxides to alter their conduction properties. The use of all possible materials to form transparent p-contacts on III-nitride flip-chip solar cells is within the scope of this invention.

The tandem III-nitride solar cells described above contained several active regions connected in series by tunnel junctions. However, one or more of the active regions could have also been connected in parallel. This alternative configuration would alleviate the need for tunnel junctions, but would necessitate the use of more than two contacts to the device. The use of multiple active regions connected in series, in parallel, or in a combination of the two is within the scope of this invention.

Advantages and Improvements

The present invention describes an improved III-nitride photovoltaic device structure and method for fabricating the improved III-nitride photovoltaic device that provides both improved manufacturability and higher performance due to increased light collection efficiency.

Previously reported III-nitride solar cells function by collecting light that was incident on the top-side of the III-nitride device layers. [1-5] In contrast, this invention describes a structure and method for collecting light that is incident on the back-side of III-nitride device layers of a flip-chip III-nitride photovoltaic device.

Use of a flip-chip device geometry in conjunction with other variations in device design should improve device efficiency by increasing the path length for light absorption [7] in the active layers of the device and by reducing the light absorption in the other layers of the device.

The proposed device can be used for converting sunlight into electricity for various commercial, industrial, or scientific applications. The proposed device can be expected to find utility in the same applications as current commercially-available solar cells.

### REFERENCES

The following references are incorporated by reference herein.

1. Jani, I. Ferguson, C. Honsberg, and S. Kurtz, Appl. Phys. Lett. 91 (2007).

2. J. Neufeld, N. G. Toledo, S. C. Cruz, M. Iza, S. P. DenBaars, and U. K. Mishra, Appl. Phys. Lett. 93 (2008).

3. A. Berkman, N. A. El-Masry, A. Emara, and S. M. Bedair, Appl. Phys. Lett. 92 (2008).

4. Chen, K. D. Matthews, D. Hao, W. J. Schaff, and L. F. Eastman, Phys. Status Solidi A 205, 1103 (2008).

5. M. Cai, S. W. Zeng, and B. P. Zhang, Appl. Phys. Lett. 95 (2009).

6. R. Krames, O. B. Shchekin, R. Mueller-Mach, G. O. Mueller, L. Zhou, G. Harbers, and M. G. Craford, J. Disp. Technol. 3, 160 (2007).

7. Nelson, The Physics of Solar Cells, 1st ed. (Imperial College Press, London, 2003).

8. Wu, W. Walukiewicz, K. M. Yu, W. Shan, J. W. Ager, E. E. Haller, H. Lu, W. J. Schaff, W. K. Metzger, and S. Kurtz, J. Appl. Phys. 94, 6477 (2003).

9. F. Muth, J. H. Lee, I. K. Shmagin, R. M. Kolbas, H. C. Casey, B. P. Keller, U. K. Mishra, and S. P. DenBaars, Appl. Phys. Lett. 71, 2572 (1997).

10. Fujii, Y. Gao, R. Sharma, E. L. Hu, S. P. DenBaars, and S. Nakamura, Appl. Phys. Lett. 84, 855 (2004).

11. Yamada, T. Mitani, Y. Narukawa, S. Shioji, I. Niki, S. Sonobe, K. Deguchi, M. Sano, and T. Mukai, Jpn. J. Appl. Phys. 41, L1431 (2002).

12. Gao, T. Fujii, R. Sharma, K. Fujito, S. P. Denbaars, S. Nakamura, and E. L. Hu, Jpn. J. Appl. Phys. 43, L637 (2004).

13. Gao, M. D. Craven, J. S. Speck, S. P. DenBaars, and E. L. Hu, Appl. Phys. Lett. 84, 3322 (2004).

14. Tanabe, Energies 2, 504 (2009).

15. Queren, M. Schillgalies, A. Avramescu, G. Bruderl, A. Laubsch, S. Lutgen, and U. Strauss, J. Cryst. Growth 311, 2933 (2009).

16. Margalith, O. Buchinsky, D. A. Cohen, A. C. Abare, M. Hansen, S. P. DenBaars, and L. A. Coldren, Appl. Phys. Lett. 74, 3930 (1999).

17. K. Ho, C. S. Jong, C. C. Chiu, C. N. Huang, C. Y. Chen, and K. K. Shih, Appl. Phys. Lett. 74, 1275 (1999).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A semiconductor device, comprising:
a III-nitride photovoltaic device, comprised of one or more III-nitride device layers, that functions by collecting light that is incident on the back-side of the III-nitride device layers.

2. The device of claim 1, wherein the III-nitride device layers are grown on a substrate.

3. The device of claim 2, wherein a planar wafer is used as the substrate for growth of the III-nitride device layers.

4. The device of claim 2, wherein a patterned wafer is used as the substrate for growth of the III-nitride device layers.

5. The device of claim 2, wherein the substrate is removed from the III-nitride device layers.

6. The device of claim 5, wherein the III-nitride device layers are exposed when the substrate is removed and the exposed III-nitride device layers are intentionally roughened.

7. The device of claim 1, wherein the III-nitride device layers contain one or more junctions of varying bandgaps.

8. The device of claim 1, wherein a grid-like p-type contact is used to contact p-type III-nitride device layers.

9. The device of claim 1, wherein a transparent or semi-transparent p-type contact is used to contact p-type III-nitride device layers of the III-nitride device layers.

10. The device of claim 1, wherein a reflective p-type contact is used to contact p-type III-nitride device layers of the III-nitride device layers.

11. A method of fabricating a semiconductor device, comprising:
fabricating a III-nitride photovoltaic device, comprised of one or more III-nitride device layers, that functions by collecting light that is incident on the back-side of the III-nitride device layers.

12. The method of claim 11, wherein the III-nitride device layers are grown on a substrate.

13. The method of claim 12, wherein a planar wafer is used as the substrate for growth of the III-nitride device layers.

14. The method of claim 12, wherein a patterned wafer is used as the substrate for growth of the III-nitride device layers.

15. The method of claim 12, wherein the substrate is removed from the III-nitride device layers.

16. The method of claim 15, wherein the III-nitride device layers are exposed when the substrate is removed and the exposed III-nitride device layers are intentionally roughened.

17. The method of claim 11, wherein the III-nitride device layers contain a plurality of junctions of varying bandgaps.

18. The method of claim 11, wherein a grid-like p-type contact is used to contact p-type III-nitride device layers of the III-nitride device layers.

19. The method of claim 11, wherein a transparent or semi-transparent p-type contact is used to contact p-type III-nitride device layers of the III-nitride device layers.

20. The method of claim 11, wherein a reflective p-type contact is used to contact p-type III-nitride device layers of the III-nitride device layers.

21. A device fabricated by the method of claim 11.
